(19) United States
(12) Patent Application Publication
(10) Pub. No.: US 2011/0042712 A1
(43) Pub. Date: Feb. 24, 2011

(54) TYPE OF GAPLESS SEMICONDUCTOR MATERIAL

(76) Inventor: Xiaolin Wang, New South Wales (AU)

Correspondence Address: FISH & RICHARDSON P.C. (BO), P.O. BOX 1022, MINNEAPOLIS, MN, 55440-1022, US

(21) Appl. No.: 12/921,644

(22) PCT Filed: Mar. 12, 2009
(86) PCT No.: PCT/AU2009/000293

§ 371 Date: Nov. 9, 2010

(30) Foreign Application Priority Data
Mar. 12, 2008 (AU) 2008901173

(51) Int. Cl. H01L 33/26; H01B 1/00; H01F 1/00; C01G 21/02; H01B 1/02; H01B 1/04; B82Y 30/00

(52) U.S. Cl. 257/103; 252/500; 252/62.51 R; 423/594.9; 252/519.1; 252/513; 252/503; 257/E33.013; 977/734

(57) ABSTRACT

The present disclosure provides a new type of gapless semiconductor material having electronic properties that can be characterized by an electronic band structure which comprises valence and conduction band portions VB₁ and CB₁, respectively, for a first electron spin polarisation, and valence and conducting band portions VB₂ and CB₂, respectively, for a second electron spin polarisation. The valence band portion VB₁ has a first energy level and one of CB₁ and CB₂ have a second energy level that are positioned so that gapless electronic transitions are possible between VB₁ and the one of CB₁ and CB₂, and wherein the gapless semiconductor material is arranged so that an energy bandgap is defined between VB₂ and the other one of CB₁ and CB₂.

### FIELD OF THE INVENTION

The present invention broadly relates to a semiconductor material and relates particularly to a gapless semiconductor material.

### BACKGROUND OF THE INVENTION

A field of technology that exploits both the spin state and charge of electrons is commonly referred to as ‘spintronics’. Materials that are currently being used for spintronic applications include diluted magnetic semiconductors, ferromagnetic materials and half metallic materials.

Diluted magnetic semiconductors do not achieve 100% electron spin polarisation in most cases and the speed of mobile electrons is reduced due to electron scattering. Diluted magnetic semiconductors are also currently confined to use at relatively low temperatures as they must be ferromagnetic in order to show some degree of spin polarizations.

Conductive ferromagnetic materials can also be used to create spin polarised currents for spintronic use but are not able to achieve %100 electron spin polarisation. Again this reduces electron mobility due to electron scattering. Further, ferromagnetic materials are not semiconducting and so their applications are limited to selected spintronic devices such as spin valves.

Half metallic materials can be used to achieve 100% spin polarization, but the charge carriers and their concentration cannot be adjusted or controlled. Consequently, the half metallic materials cannot be used for semiconductor based spintronic device applications.

There is a need for technological advancement.

### SUMMARY OF THE INVENTION

The present invention provides in a first aspect a new type of gapless semiconductor material having electronic properties that can be characterized by an electronic band structure, the electronic band structure comprising valence and conduction band portions VB₁ and CB₁, respectively, for a first electron spin polarisation, and valence and conducting band portions VB₂ and CB₂, respectively, for a second electron spin polarisation;
wherein VB₁ has a first energy level and one of CB₁ and CB₂ have a second energy level that are positioned so that gapless electronic transitions are possible between VB₁ and the one of CB₁ and CB₂, and wherein the gapless semiconductor material is arranged so that an energy bandgap is defined between VB₂ and the other one of CB₁ and CB₂.

Throughout this specification the term “gapless” is used for an energy gap that of approximately 0.1 eV or smaller than 0.1 eV.

The gapless semiconductor material typically is arranged so that the Fermi level is, without an external influence, positioned in the proximity of the maximum of VB₁.

The first energy level typically is a maximum of VB₁ and the second energy level typically is a minimum of the one of CB₁ and CB₂.

Throughout this specification, the term “external influence” is used for any force, field or the like that results in a shift of the Fermi level relative to the electronic bands of the gapless semiconductor material. For example, the external influence may be provided in the form of an electrical field associated with a voltage applied across the gapless semiconductor material.

Gapless electronic transitions, requiring only a very small excitation energy, are possible between VB₁ and the one of CB₁ and CB₂. However, an energy gap is defined between VB₂ and the other one of CB₁ and CB₂ and energy is required for electronic excitations from VB₂ to CB₁ or CB₂. Consequently, the gapless semiconductor material has the significant advantage that gapless electronic excitations are possible and all excited electrons and/or hole charge carriers, up to a predetermined excitation energy, have the same spin polarization.

The bandgap may be a direct or an indirect bandgap. Further, gapless transitions may be a direct or indirect transitions.

Because gapless electronic transitions are possible, the electronic properties of the gapless semiconductor material typically are very sensitive to a change in external influences, such as a change in an external magnetic or electric fields, temperature or pressure, light and strain etc. The full spin polarisation reduces electron scattering probabilities and consequently the electron mobility typically is relatively large, such as 1 to 2 orders of magnitude larger than that of conventional semiconductor materials. The gapless semiconductor material according to an embodiment of the present invention combines the advantages of gapless electronic transitions in a semiconductor material with full spin polarisation and consequently opens avenues for new applications, such as new or improved “spintronic”, electronic, magnetic, optical, mechanical and chemical sensor devices applications.

The energy maximum of VB₁ and the energy minimum of the one of CB₁ and CB₂ may for example have an energetic separation in the range of 0-0.01 eV, 0-0.02 eV, 0-0.04 eV, 0-0.05 eV, 0-0.06 eV, 0-0.08 eV, 0-0.1 eV and may also have a slight overlap.

The predetermined energy depends on the energetic position of the energetic band portions relative to each other. The predetermined energy typically is within the range of 0 eV to E_{G} or 0 to 0.5 E_{G} (E_{G}: bandgap energy). The bandgap energy E_{G} typically is in the range of 0.2 to 5 eV or 0.2 to 3 eV.

The gapless semiconductor material typically is arranged so that electronic properties are controllable by controlling the position of the Fermi level relative to the energy bands. For example, the gapless material may be arranged so that a shift of the Fermi level position relative to the energy bands by a predetermined energy results in generation of fully polarised free charge carriers. In one specific example the gapless semiconductor material is arranged so that a predetermined shift of the Fermi level relative to the energy bands results in a change in one type of fully polarised charge carriers to another type of fully polarised charge carriers with and without a change in polarisation.

The gapless semiconductor may be arranged so that electrons excited from VB₁ or VB₂ to CB₁ or CB₂ have full spin polarisation. Alternatively or additionally, the gapless semiconductor may be arranged so that hole charge carriers in VB₁ or VB₂ have full spin polarisation.

In a first embodiment of the present invention the maximum of VB₁ and the minimum of CB₁ are positioned in the proximity of each other and typically in the proximity of the Fermi level. In this embodiment the bandgap E_{G} is defined between VB₂ and CB₂. For example, the maximum of VB₂ may be positioned at the Fermi level and the minimum of CB₂ may be positioned at an energy of E_{G} above the Fermi level. In this case all electrons that were excited from VB₁ to CB₁ have the same spin polarisation for an excitation energy up to E_{G}. Alternatively, the minimum of CB₂ may be positioned at the Fermi level or the maximum of VB₂ may be positioned below the Fermi level. In this case all hole charge carriers in VB₁ have the same spin polarization for an excitation energy up to E_{G}. In a further example, the material may be arranged so that the Fermi level is positioned substantially in the middle of the bandgap. In this case all electrons excited from VB₁ to CB₁ have the same spin polarisation for an excitation energy up to 0.5 E_{G} and also all corresponding hole charge carriers in VB₁ have the same spin polarisation.

In a second embodiment of the present invention the maximum of VB₁ and the minimum of CB₂ are positioned in the proximity of each other and typically in the proximity of the Fermi level. In this embodiment a first bandgap is defined between VB₁ and CB₁ and a second bandgap typically is defined between VB₂ and CB₂. A gapless electronic transition from VB₁ to CB₂ is associated with a change in spin polarisation. In this embodiment the gapless semiconductor material is arranged so that electrons excited from VB₁ to CB₂ have full spin polarisation up to an excitation energy that corresponds to an energy difference between the minimum of CB₁ and the minimum of CB₂ and corresponding hole charge carriers of VB₁ have full opposite spin polarisation.

In the above-described second embodiment of the present invention the gapless semiconductor material typically is arranged so that, if the Fermi level is shifted by an external influence below the maximum of VB₁ to a position at or above the maximum of VB₂, fully polarised hole charge carriers are generated in VB₁. Further, the gapless semiconductor material typically is arranged so that, if the Fermi level is shifted by the external influence above the maximum of VB₁ to a position at or below the minimum of CB₂, CB₂ includes fully polarised electrons, which are polarised in a direction that is opposite to that of the polarised hole charge carriers in VB₁ generated by lowering the Fermi level.

The gapless semiconductor material may have a dispersion relation that is at least in part a substantially quadratic function of momentum. Alternatively, the material may also have a dispersion relation that is at least in part a substantially linear function of momentum.

The gapless semiconductor material may be provided in any suitable form and typically comprises an indirect or direct gapless semiconductor material that is doped with magnetic ions.

The gapless semiconductor material may comprise a material that is associated with a transition from half metal to magnetic semiconductor. In one specific embodiment of the present invention the gapless semiconductor material is provided in the form of an oxide material, such as a material of the type AₓB_{y}O_{z} where A is a group 1, group 2 or rare earth element. B is a transition metal and the parameters x, y and z are typically within the range of 0-4. For example, the gapless material may comprise a lead-based oxide, and typically comprises PbPdO₂. In this embodiment the gapless semiconductor material is doped with Cobalt ions and at least some, typically approximately 25%, of the Palladium ions of the PbPdO₂ are replaced by the Cobalt ions. The inventor has observed that PbPdO₂ doped with Cobalt is a material that has electronic properties in accordance with the above-described second specific embodiment of the present invention.

Alternatively, the gapless semiconductor material may comprise any suitable type of graphene (a single layer of graphite with or without doping and with or without modifications to surfaces and/or edges or any type of gapless semiconductor material or narrow band materials that is doped in a suitable manner.

The valence band and conduction bands of the gapless semiconductor material may have band bendings that are chosen so that excited polarised electrons and hole charge carriers have differing speeds whereby separation of the excited electrons and hole charge carriers from each other is facilitated.

The present invention provides in a second aspect a source of polarized light, the source comprising:
the new type of gapless semiconductor material in accordance with the first aspect of the present invention;
an excitation source for exciting electrons from VB₁ to the one of CB₁ and CB₂ and arranged so that an excitation energy is insufficient for exciting electrons from VB₁ to the other one of CB₁ and CB₂.

The other one of CB₁ and CB₂ typically is CB₂. The excitation source may be a photon source. The source of polarised light typically is arranged so that electron transitions from VB₂ to the either CB₁ or CB₂ are substantially avoided.

The above-defined source of polarized photons typically is arranged so that excited electrons and holes have a spin that is predetermined by possible electronic transitions and recombination of the excited electrons and the holes typically results in emission of polarized photons.

The present invention provides in a third aspect a source of polarized light, the source comprising:
a semiconductor material having electronic properties that can be characterized by an electronic band structure, the electronic band structure comprising valence and conduction band portions VB₁ and CB₁, respectively, for a first electron spin polarisation, and valence and conducting band portions VB₂ and CB₂, respectively, for a second electron spin polarisation wherein VB₁, VB₂, CB₁ and CB₂ have energy levels that are arranged so first and second bandgaps are being formed, the first bandgap being smaller than the second bandgap;
an excitation source for exciting electrons across the first bandgap and arranged so that an excitation energy is insufficient for exciting electrons across the second bandgap.

VB₁, VB₂, CB₁ and CB₂ typically have energy levels that are arranged so that the first energy bandgap is defined between VB₁ and CB₁ and the second energy bandgap between VB₂ and CB₂. The excitation source typically is arranged for exciting electrons from VB₁ to CB₁ and arranged so that an excitation energy is insufficient for exciting electrons from VB₂ to CB₂.

The excitation source may be a photon source. The source of polarized electrons typically is arranged so that electronic excitations form VB₁ to CB₂ and/or from VB₂ to CB₁ are substantially avoided.

The present invention provides in a fourth aspect a gapless semiconductor material comprising an oxide material and having electronic properties that can be characterized by an electronic band structure, the electronic band structure comprising a valence band VB and a conduction band CB;
wherein VB and CB are positioned so that gapless electronic transitions are possible between VB and CB.

The oxide material typically is of the type AₓB_{y}O_{z} where A is a group 1, group 2 or rare earth element. B is a transition metal and the parameters x, y and z are typically within the range of 0-4. In one specific example the gapless semiconductor material is a lead-based oxide such as PbPdO₂.

Alternatively, the gapless semiconductor material may be provided in the form of AₓB_{y}C_{z}D_{q}Oₜ where A and B are a group 1, group 2 or rare earth element, C and D are transition metal and elements in III, VI, and V family, O is oxygen, and the parameters x, y, z, q, t are within the range of 0-12.

The present invention provides in a third aspect an electronic device comprising the gapless semiconductor material in accordance with the first or second aspect of the present invention.

The electronic device typically comprises a component for generating an external influence and thereby shifting a Fermi level position of the gapless semiconductor material relative to energy bands. Further, the electronic device may comprise a separator for separating excited polarised electrons and hole charge carriers from each other. In one embodiment the separator is arranged to operate in accordance with the principles of the Hall effect.

The invention will be more fully understood from the following description of specific embodiments of the invention. The description is provided with reference to the accompanying drawings.

### BRIEF DESCRIPTION OF THE DRAWINGS

FIGS. 1 (a) to 1 (d) show schematic electronic band structures of materials in accordance with embodiments of the present invention;

FIGS. 2 (a) to 2 (d) show schematic electronic band structures of gapless semiconductor materials in accordance with further embodiments of the present invention;

FIG. 3 illustrates a source of polarized light in accordance with a specific embodiment of the present invention;

FIG. 4 shows a representation of the crystallographic structure of a gapless semiconductor material in accordance with an embodiment of the present invention;

FIGS. 5 (a) and 5(b) show band structure diagrams of the material according to a specific embodiment of the present invention;

FIG. 6 shows a representation of the crystallographic structure of a gapless semiconductor material in accordance with another embodiment of the present invention;

FIGS. 7 (a) and 7(b) show band structure diagrams of the material according to a specific embodiment of the present invention;

FIG. 8 shows an electronic device in accordance with an embodiment of the present invention; and

FIG. 9 illustrates the function of the electronic device as shown in FIG. 8.

### DETAILED DESCRIPTION OF SPECIFIC EMBODIMENTS

Embodiments of the present invention provide a gapless semiconductor material that is arranged for full spin polarization of excited electrons and/or hole charge carriers up to a predetermined excitation energy. The gapless semiconductor material combines the advantages of gapless semiconductor transitions with those of full spin polarization and consequently opens new avenues for new or improved electronic, magnetic, optical, mechanical and chemical sensor devices applications

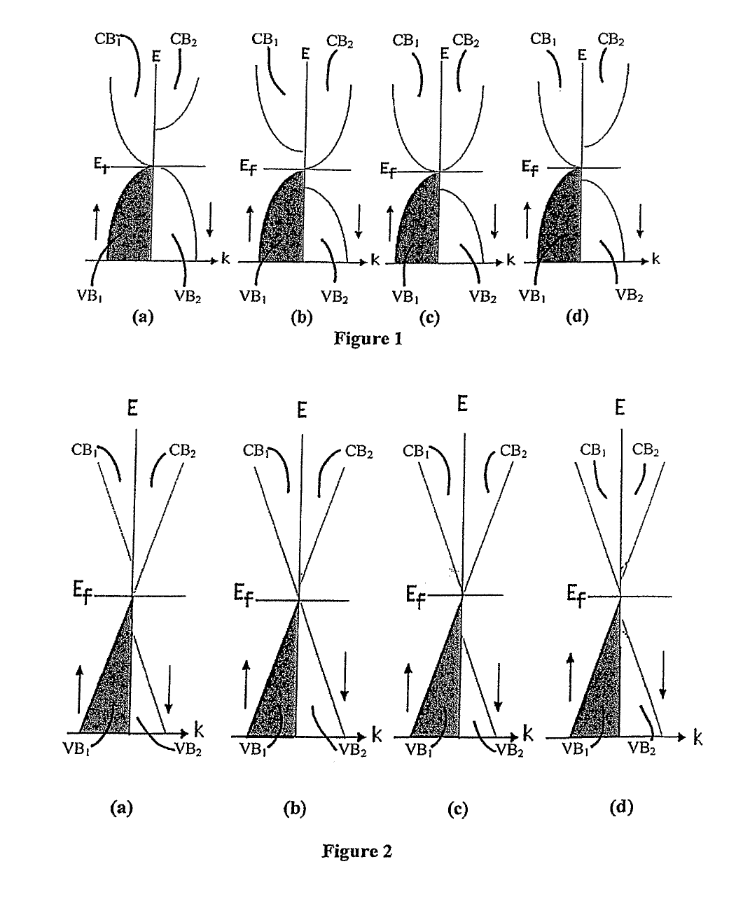

With reference to FIG. 1, specific examples of band structures of gapless semiconductor materials in accordance with the embodiments of present invention are now described.

FIG. 1 (a) shows a schematic representation of an energy band diagram of gapless semiconductor material in accordance with a first specific embodiment of the present invention. The shown band diagram illustrates a dispersion relation of the material (energy E as a function of momentum k). The energy band diagram shows the Fermi level E_{F} separating a valence band from a contracting band. The valence band is divided into a first valance portion of VB₁ and a second valance portion VB₂ and the conducting band is divided into a first conducting band portion CB₁ and a second conducting band portion CB₂. The band portions VB₁ and CB₁ represent possible energetic states of electrons having a first spin polarisation and the band portions VB₂ and CB₂ represent possible electronic states associated with an opposite spin polarisation. In this embodiment, the maximum of the band portion VB₁ and the minimum of the band portion CB₁ are positioned at the Fermi level in a manner so that gapless transitions are possible from VB₁ to CB₁.

In this embodiment the maximum of the valance band portion VB₂ is also positioned at the Fermi level, but the minimum of the conducting band portion CB₂ is separated from the maximum of the valance band portion VB₂ by a bandgap. Consequently, for electronic transitions from the valance band into the conducting band the only available empty electronic states are those of CB₁ that are positioned at an energy between the Fermi level and the minimum CB₂ if the excitation energy is below an energy that corresponds to the bandgap. In this case, all excited electrons are fully polarized.

The energetic position of the Fermi level relative to the energy bands of the gapless semiconductor material can be altered by an external influence such as an external voltage applied across the gapless semiconductor material. The charge carrier concentration may be controlled by choosing the position of the Fermi level relative to the energy bands. For example, if the Fermi level is lifted relative to the energy bands to a position below the minimum of CB₂, the conducting band portion CB₁ has occupied electronic states that are fully polarized.

FIG. 1 (b) shows a band diagram of a material in accordance with another specific embodiment of the present invention. In this embodiment the valance band portion VB₁ is separated from the conducting band portions CB₁ by an energy gap and the valance band portion VB₂ is also separated from the conducting band portion CB₂ by an energy gap. However, there is no energy gap (or only a small energy gap having an energy of less than 0.1 eV) between VB₁ and CB₂. Consequently, gapless transitions are possible between VB₁ and CB₂. Such gapless transitions transfer the electrons from a first spin direction (that of VB₁) to an opposite spin direction (that of CB₂). For electronic transitions from VB₁ or VB₂ to CB₂ having an energy that is below that of the energy of the bandgap between VB₁ and CB₁, all excited electrons in CB₂ are fully spin polarized. Further, the corresponding hole charge carriers in VB₁ are also fully polarized in an opposite direction.

For example, the Fermi level position may be lifted to a slightly higher energy, but below the minimum of CB₁. In this case, CB₂ would contain occupied electronic states that are fully polarized. If, on the other hand, the Fermi level is slightly shifted to a lower position but above the maximum of VB₂, fully polarized hole charge carriers are generated in VB₁. The generated hole charge carriers have a polarization that is opposite that of the occupied electronic states generated by lifting the Fermi level. Consequently, it is possible to change the type of charge carriers and their polarization by controlling the Fermi level position using an external influence.

FIG. 1 (c) shows an energy band diagram of a gapless semiconductor material in accordance with a further embodiment of the present invention. In this case, gapless transitions are possible between VB₁ and VB₂. The minimum of CB₂ is positioned at the Fermi level and an energy gap is formed between VB₂ and CB₂. Electronic transitions from VB₁ to CB₁ or CB₂ result in generation of fully polarised hole charge carriers VB₁ if the excitation energy is below an energy that corresponds to the bandgap between VB₂ and CB₂. Further, if the Fermi level is slightly lowered by an energy that is smaller than the bandgap between VB₂ and CB₂, fully polarized hole charge carriers are generated in VB₁.

FIG. 1 (d) shows a band diagram of a gapless semiconductor material in accordance with a further specific embodiment of the present invention. In this case, gapless transitions are possible between VB₁ and CB₁. and the bandgap is defined between VB₂ and CB₂. In this embodiment Fermi level is positioned approximately in the middle of the Bandgap. Electronic transitions from VB₁ to CB₁ result in generation of fully polarised electrons in CB1 and fully polarised hole charge carriers in VB₁ if the excitation energy is below an energy that corresponds to approximately half of the bandgap energy. Further, if the Fermi level is slightly lifted to a position below the minimum of CB₂, fully polarized electronic states are generated in CB₁. Alternatively, if the Fermi level is lowered to a position above the maximum of VB₂, polarized hole charge carriers are generated in VB₁.

FIG. 1 shows the energy bands for parabolic dispersions relations. FIG. 2 shows the corresponding band diagrams for the case the dispersion relation is assumed to be linear.

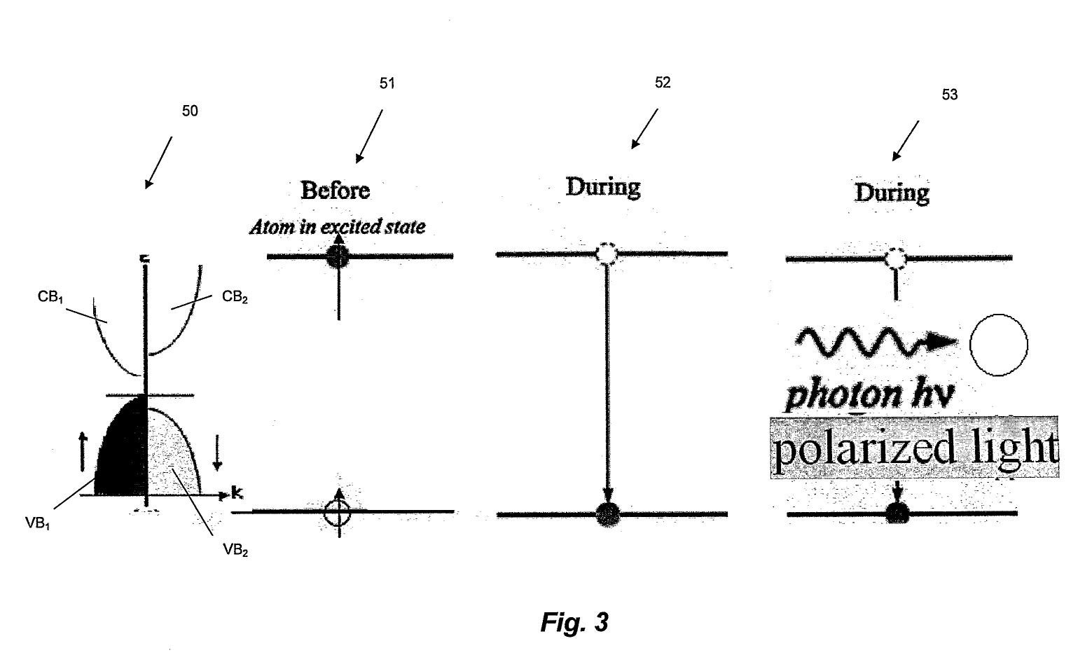

FIG. 3 illustrates the operation of a source of polarised light in accordance with a specific embodiment of the present invention. FIG. 3 shows a band diagram 50 for a semiconductor material. For example, the semiconductor material may be of the type as described above with reference to FIG. 1. Alternatively, the semiconductor material may not be a gapless material but may have respective bandgaps for each electron spin polarisation.

FIG. 3 shows a band diagram 50 having a valance band VB₁ and a conducting band CB₁ for a first electron spin direction and a valance and VB₂ and a conducting band CB₂ for a second electron spin direction. In this example, a first bandgap is defined between VB₁ and CB₁ and a second bandgap is defined between VB₂ and CB₂. The first energy bandgap is smaller than the second energy bandgap. Steps 51-53 illustrate electron excitation, re-combination and emission of polarised photons. In the described embodiment a photon source is used to excite electrons from VB₁ to CB₁. The photon energy is insufficient for excitation of electrons to CB₂ of electrons from VB₂ to CB₁ Consequently, the excited electrons and hole states have one predetermined spin polarisation. It follows that recombination of these excited states results in emission of polarised photons.

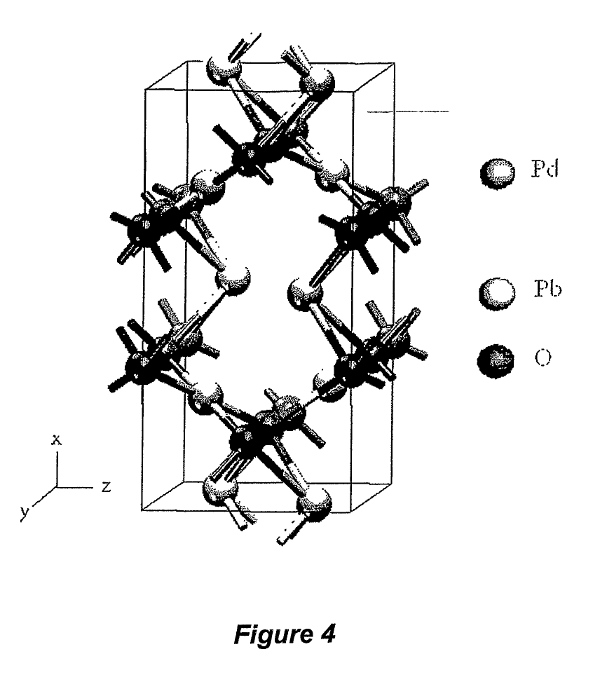

The gapless semiconductor may for example be provided in the form of an AₓB_{y}O_{z} oxide material, where A is a group 1, group 2 or rare earth element. B is a transition metal or III, IV, V family elements and the parameters x, y and z are within the range of 0-4. In this example the gapless material comprises PbPdO₂. In this embodiment the gapless semiconductor material is doped with Co ions and approximately 25% of the Pd ions of the PbPdO₂ are replaced by the Co ions. FIG. 4 illustrates the crystallographic structure of that material. The inventor has observed that PbPdO₂ doped with Co is a gapless semiconductor material that has electronic properties in accordance with the above-described second specific embodiment of the present invention.

The PbPdO₂ material may be formed by mixing powders of PdO, PdO and CoCO₃. The mixture is then palletized and then sintered at a temperature of approximately 600-900° C. for approximately 3-10 hours. For the manufacture of thin film samples a bulk target of Pb—Pd—Co—O may initially be formed and then a pulsed laser deposition method may be used to deposit the thin film material on suitable substrates at a temperature of approximately 400-900° C. in an atmosphere of Argon with oxygen partial pressure.

It is to be appreciated by a person skilled in the art that the gapless semiconductor material may be provided in many different forms. Generally, the specific gapless semiconductor material having the described properties typically comprises a gapless semiconductor material that is doped with a suitable dopant, typically magnetic ions. Alternatively, the gapless semiconductor material may comprise any other suitable type of material doped with magnetic ions including graphine and Hg based IV-VI materials such as HgCdTe, HgCdSe or HgZnSe.

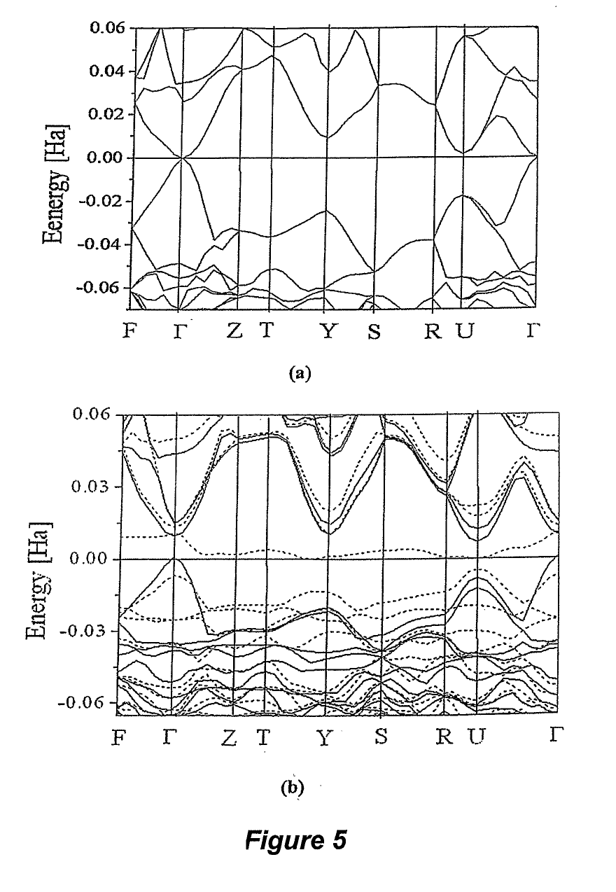

FIG. 5(a) shows an electronic band structure for PbPdO₂ calculated for high symmetry points in the Brillouin zone.

FIG. 5(a) indicates that there is no forbidden band or bandgap present at the Γ point indicating that PbPdO₂ is a typical direct gapless semiconductor (direct refers to transitions across the bandgap).

FIG. 5(b) shows a spin resolved electron band structure of PbPdO₂ with a 25% doping level of Co. The solid lines in 5(b) indicate the band structure of “spin up” electrons. The dotted lines in FIG. 5(b) indicate the band structure of “spin down” electrons. FIG. 4(b) shows an electronic band structure that relates to that shown in FIG. 1(b).

FIG. 5(b) shows that for Co-doped PbPdO₂, the highest valence band of the spin up electrons is adjacent the Fermi level at the Γ points. The lowest conduction band is also adjacent the Fermi level at the U point and between the T and Y points. The valence band of the spin up electrons (VB1) and the conduction band of the spin down electrons (CB2) is therefore shown to be indirectly gapless.

The band structures shown in FIGS. 5(a) and 5(b) were calculated using density functional theory implemented using suitable computer software. When these calculations were performed, the following variables were set:
the local density approximation was used for the exchange-correction functional
a Monkhort-pack grid (4×4×6) with 96 summarised k-points was used for Brillouin sampling with a cut-off energy of 340 eV and a SFC tolerance of 10⁻⁶
k-point separation quality for the band structure was set to 0.015 A⁻¹
   relativistic electrons were used for the core treatment

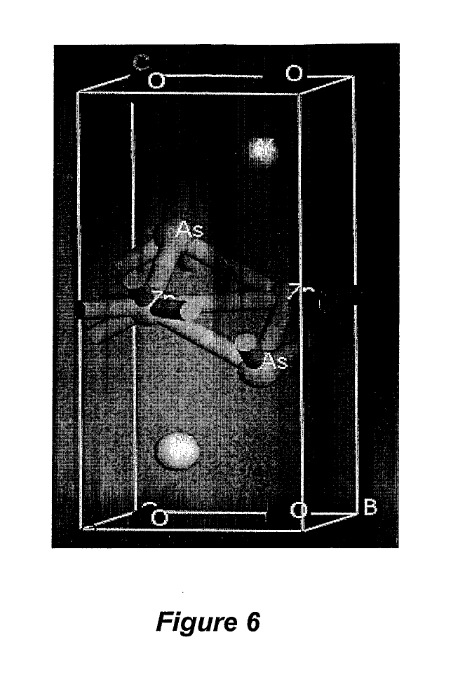

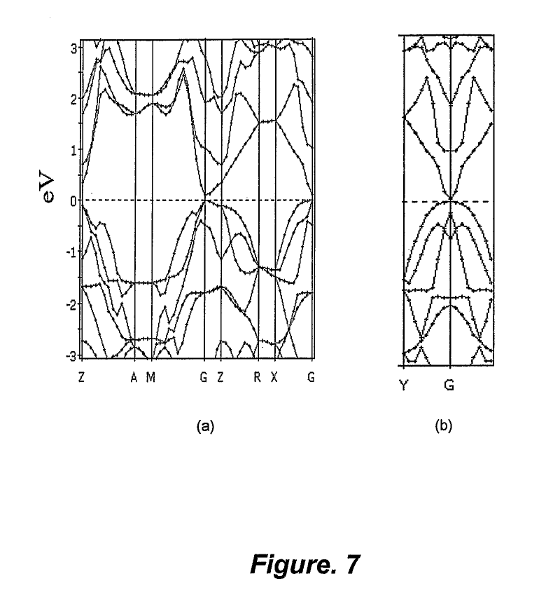

FIG. 6 illustrates the crystallographic structure of a further material. The inventor has observed that YFeAsO is a semiconductor material that has properties similar to those of the above-described material. FIGS. 7 (a) and 7 (b) show the band structures of this material.

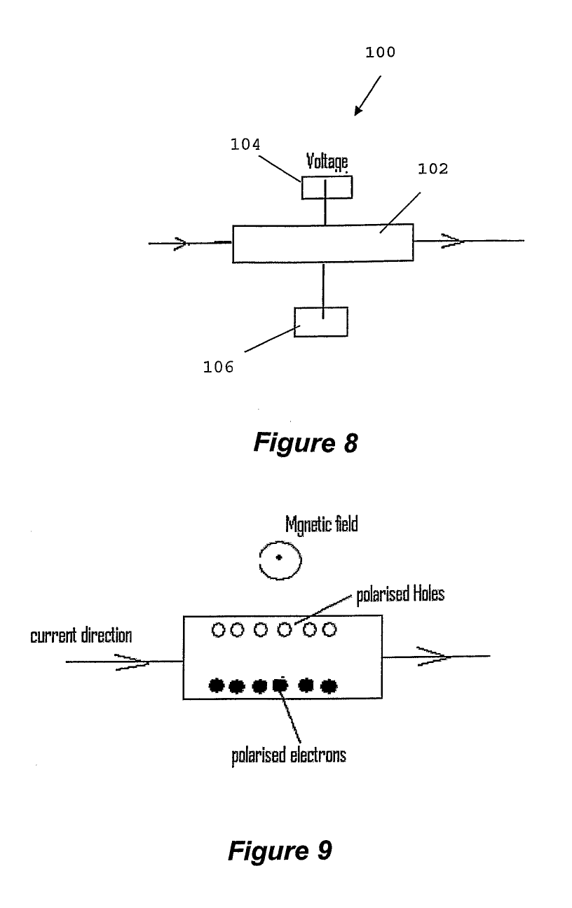

FIG. 8 shows an electronic device 100 in accordance with an embodiment of the present invention. In this embodiment the electronic device comprises an element 102 including the above-described gapless semiconductor material. Further, the electronic device 100 comprises an external source 104 for applying an external influence and thereby shifting the Fermi level position of the gapless semiconductor material. In this embodiment the external source is provided in the form of a voltage source.

The electronic device 100 comprises a separator 106 that is arranged to separate electrons from hole charge carriers. The separator 106 is arranged for generating a magnetic field. Electrons and hole charge carriers that move through the material 102 in a direction as indicated by arrows in FIG. 8 are separated from each other in the magnetic field by the Hall effect. This is schematically illustrated in FIG. 9.

Although the invention has been described with reference to particular examples, it will be appreciated by those skilled in the art that the invention may be embodied in many other forms. For example, the gapless semiconductor material may not be an oxide material. Further, a person skilled in the art will appreciate that the band structure diagrams shown in FIGS. 1 and 2 are only simplified examples of many possible variations. Further, it is to be appreciated that spin gapless materials may be provided in the form of two dimensional graphene with or without doping or in any form of grapheme and may also be provided in the form of a material having conductive surfaces.

1. A gapless semiconductor material having electronic properties that can be characterized by an electronic band structure, the electronic band structure comprising valence and conduction band portions VB₁ and CB₁, respectively, for a first electron spin polarisation, and valence and conducting band portions VB₂ and CB₂, respectively, for a second electron spin polarisation;
wherein VB₁ has a first energy level and one of CB₁ and CB₂ have a second energy level that are positioned so that gapless electronic transitions are possible between VB₁ and the one of CB₁ and CB₂, and wherein the gapless semiconductor material is arranged so that an energy bandgap is defined between VB₂ and the other one of CB₁ and CB₂.

2. The gapless semiconductor material of claim 1 wherein the first energy level is a maximum of VB₁ and the second energy level is a minimum of the one of CB₁ and CB₂.

3. The gapless semiconductor material of claim 1 arranged so that the Fermi level is, without an external influence, positioned in the proximity of a maximum of VB₁.

4. The gapless semiconductor material of claim 1 wherein an energy maximum of VB₁ and an energy minimum of the one of CB₁ and CB₂ have an energetic separation in the range of 0-0.01 eV, 0-0.02 eV, 0-0.04 eV, 0-0.05 eV, 0-0.06 eV, 0-0.08 eV or 0-0.1 eV.

5. The gapless semiconductor material of claim 1 wherein the gapless semiconductor material is arranged so that electronic properties are controllable by controlling the position of the Fermi level relative to the energy bands.

6. The gapless semiconductor material of claim 1 wherein the gapless material is arranged so that a shift of the Fermi level position relative to the energy bands by a predetermined energy results in generation of fully polarised free charge carriers.

7. The gapless semiconductor material of claim 6 wherein the predetermined energy is within the range of 0 eV to E_{G} or 0 to 0.5 E_{G} (E_{G}: energy of the bandgap).

8. The gapless semiconductor material of claim 1 wherein the energy of the bandgap E_{G} is in the range of 0.2 to 5 eV or 0.2 to 3 eV.

9. The gapless semiconductor of claim 1 arranged so that electrons excited from VB₁ or VB₂ to CB₁ or CB₂ have full spin polarisation.

10. The gapless semiconductor of claim 1 arranged so that hole charge carriers in VB₁ or VB₂ have full spin polarisation.

11. The gapless semiconductor material of claim 1 wherein a maximum of VB₁ and a minimum of CB₁ are positioned in the proximity of each other and wherein the bandgap E_{G} is defined between VB₂ and CB₂.

12. The gapless semiconductor material of claim 1 wherein the gapless semiconductor material is arranged so that a predetermined shift of the Fermi level relative to the energy bands results in a change one type of fully polarised charge carriers to another type of fully polarised charge carriers.

13. The gapless semiconductor of claim 1 wherein a maximum of VB₁ and a minimum of CB₂ are positioned in the proximity of each other, a first bandgap is defined between VB₁ and CB₁ and a second bandgap is defined between VB₂ and CB₂ and wherein a gapless electronic transition from VB₁ to CB₂ is associated with a change in spin polarisation.

14. The gapless semiconductor of claim 13 arranged so that electrons excited from VB₁ to CB₂ have full spin polarisation up to an excitation energy that corresponds to an energy difference between the minimum of CB₁ and the minimum of CB₂ and corresponding hole charge carriers of VB₁ have full opposite spin polarisation.

15. The gapless semiconductor material of claim 1 comprising an indirect or direct gapless semiconductor material that is doped with magnetic ions.

16. The gapless semiconductor material of claim 1 comprising a material that is associated with a transition from half metal to magnetic semiconductor.

17. The gapless semiconductor material of claim 1 provided in the form of an oxide material.

18. The gapless semiconductor material of claim 1 provided in the form AₓB_{y}O_{z} where A is a group 1, group 2 or rare earth element, B is a transition metal and the parameters x, y and z are within the range of 0-4.

19. The gapless semiconductor material of claim 1 comprising a lead-based oxide.

20. The gapless semiconductor material of claim 1 comprising PbPdO₂.

21. The gapless semiconductor material of claim 20 being a material that is doped with Cobalt ions.

22. The gapless semiconductor of claim 21 wherein the Cobalt ions replace a portion of the Palladium ions.

23. The gapless semiconductor material of claim 1 comprising one of graphene and Hg based IV-VI materials.

24. A source of polarized light, the source comprising:
the new type of gapless semiconductor of claim 1;
an excitation source for exciting electrons from VB₁ to the one of CB₁ and CB₂ and arranged so that an excitation energy is insufficient for exciting electrons from VB₁ to the other one of CB₁ and CB₂.

25. The source of polarized light of claim 24 wherein the excitation source is a photon source.

26. The source of polarized light of claim 24 wherein the source of polarised light is arranged so that electron transitions from VB₂ to the either CB₁ or CB₂ are substantially avoided.

27. A source of polarized light, the source comprising:
a semiconductor material having electronic properties that can be characterized by an electronic band structure, the electronic band structure comprising valence and conduction band portions VB₁ and CB₁, respectively, for a first electron spin polarisation, and valence and conducting band portions VB₂ and CB₂, respectively, for a second electron spin polarisation wherein VB₁, VB₂, CB₁ and CB₂ have energy levels that are arranged so first and second bandgaps are being formed, the first bandgap being smaller than the second bandgap;
an excitation source for exciting electrons across the first bandgap and arranged so that an excitation energy is insufficient for exciting electrons across the second bandgap.

28. The source of polarised light of claim 27 wherein VB₁, VB₂, CB₁ and CB₂ have energy levels that are arranged so that the first energy bandgap is defined between VB₁ and CB₁ and the second energy bandgap VB₂ and CB₂.

29. The source of polarised photons of claim 27 wherein the excitation source is arranged for exciting electrons from VB₁ to CB₁ and arranged so that an excitation energy is insufficient for exciting electrons from VB₂ to CB₂.

30. The source of polarized light of claim 27 wherein the excitation source is a photon source.

31. The source of polarized light of claim 27 wherein the source of polarized light is arranged so that excitations form VB₁ or VB₂, to CB₂ are substantially avoided.

32. A gapless semiconductor material comprising an oxide material and having electronic properties that can be characterized by an electronic band structure, the electronic band structure comprising a valence band VB and a conduction band CB;
wherein VB and CB are positioned so that gapless electronic transitions are possible between VB and CB.

33. The gapless semiconductor material of claim 32 wherein the oxide material is of the type AₓB_{y}O_{z} where A is a group 1, group 2 or rare earth element, B is a transition metal and the parameters x, y and z are within the range of 0-4.

34. The gapless semiconductor material of claim 33 wherein the oxide material is of the type AₓB_{y}C_{z}D_{q}O_{tz} where A and B are a group 1, group 2 or rare earth element, C and D are transition metal and elements in III, VI, and V family, O is oxygen, and the parameters x, y, z, q, t are within the range of 0-12.

35. The gapless semiconductor material of claim 32 wherein the gapless semiconductor material is a lead-based oxide.

36. The gapless semiconductor material of claim 32 wherein the gapless semiconductor material is PbPdO₂.

37. An electronic device comprising the gapless semiconductor material of claim 1.

38. The electronic device of claim 37 comprising a component for generating an external influence and thereby shifting a Fermi level position of the gapless semiconductor material relative to energy bands.

39. The electronic device of claim 37 comprising a separator for separating excited polarised electrons and hole charge carriers from each other.
